(19) United States
(12) Patent Application Publication
(10) Pub. No.: US 2007/0080453 A1
(43) Pub. Date: Apr. 12, 2007

(54) Semiconductor chip having a bump with conductive particles and method of manufacturing the same

(75) Inventors: Woo-jin Jang, Seoul (KR); Seung-won Lee, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/542,283

(22) Filed: Oct. 3, 2006

(30) Foreign Application Priority Data
Oct. 6, 2005 (KR) 10-2005-0094076

(51) Int. Cl. H01L 23/48; H01L 21/44

(52) U.S. Cl. 257/737; 438/613; 257/E23.021

(57) ABSTRACT

A semiconductor chip includes a plurality of chip pads and a plurality of bumps formed on respective chip pads, each bumps including a bump main body and a conductive particle disposed on the bump main body and exposed to the air, the conductive particle including an elastic portion made of an elastic material and a conductive layer enclosing the elastic portion.

### RELATED APPLICATION

This application relies for priority on Korean Patent Application No. 10-2005-0094076, filed in the Korean Intellectual Property Office on Oct. 6, 2005, the entire contents of which are incorporated herein by reference.

### BACKGROUND OF THE INVENTION

1. Field of the Invention

The present invention relates to a semiconductor chip and a method of manufacturing the same. More particularly, the present invention relates to a semiconductor chip having a cost-effective bump and a method of manufacturing the same.

2. Description of the Related Art

The need for thin, slim and light semiconductor chips has led to a semiconductor chip directly mounted on an external board, that is, a flip chip. The flip chip is a semiconductor chip having bumps thereon, so that the bumps can be directly electrically connected to an external board.

The flip chip has the advantages of enabling the realization of thin, slim and small electronic goods, and of reducing the distance between a semiconductor chip and an external board, thereby reducing inductance.

Currently known flip chip assembly technologies have been developed based on solder bump, stud bump and gold (Au) bump technologies. However, flip chip technology using an Anisotropic Conductive Film (ACF) is currently being used in many areas. The ACF includes an adhesive resin for attaching a semiconductor chip to an external board, and conductive particles. Each conductive particle includes a polymer nucleus, a metal layer and an insulating layer plated on the surface of the polymer nucleus.

When interconnecting a flip chip to an external board, the insulating layer of the conductive particle breaks, so that the metal layer is exposed and the conductive particle is brought into the anisotropic conductive state. However, in the case in which the insulating layer does not break, the metal layer is not exposed, so that electrical connection cannot be formed.

Further, since the ACF contains lots of conductive particles that do not participate in interconnection between a semiconductor chip and an external board, the ACF assembly method is not cost-effective.

### SUMMARY OF THE INVENTION

Accordingly, a feature of the present invention is to provide a semiconductor chip having a cost-effective bump.

It is another feature of the present invention to provide a method of manufacturing a semiconductor chip having a cost-effective bump.

The advantages of the present invention are not limited to the above description, but other objects and advantages of the present invention can be readily understood by ordinary people having ordinary skill in the art from the following description.

According to a first aspect, the present invention is directed to a semiconductor chip comprising a plurality of chip pads and a plurality of bumps formed on respective chip pads. Each bump includes a bump main body electrically connected to the chip pad and a conductive particle disposed on the bump main body and exposed, each conductive particle including an elastic portion made of an elastic material and a conductive layer enclosing the elastic portion.

In one embodiment, part of the conductive particle disposed at an upper end portion of the bump main body is disposed in the bump main body.

In one embodiment, the bump main body is a stacked structure in which a conductive particle-containing layer is stacked on a conductive particle-free layer.

In one embodiment, the bump main body has one or more conductive particles embedded therein.

In one embodiment, the bump main body comprises gold (Au), nickel (Ni), copper (Co), or a combination thereof.

In one embodiment, the conductive particle has a substantially spherical shape.

In one embodiment, the conductive layer of the conductive particle is exposed.

According to another aspect, the present invention is directed to a method of manufacturing a semiconductor chip, comprising providing a semiconductor chip having a plurality of chip pads and forming bumps on respective chip pads, each bump comprising a bump main body electrically connected to the chip pad and a conductive particle disposed on the bump main body and exposed, the conductive particle including an elastic portion made of an elastic material and a conductive layer enclosing the elastic material.

In one embodiment, forming the bumps comprises: forming a lower bump through a plating process using a plating solution not containing conductive particles; and forming an upper bump through a plating process using a plating solution containing conductive particles.

In one embodiment, forming the bump comprises forming the bump main body having conductive particles embedded therein through a plating process using a plating solution containing conductive particles.

In one embodiment, the bump main body comprises gold (Au), nickel (Ni), copper (Cu), or a combination thereof.

In one embodiment, the conductive particle has a substantially spherical shape.

In one embodiment, the conductive particle does not include an insulating layer as an outermost layer.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1A is a perspective view illustrating a semiconductor chip according to a first embodiment of the present invention.

FIG. 1B is a cross-sectional view taken along the line B-B′ in FIG. 1A.

FIG. 1C is a cross-sectional view illustrating a conductive particle used in the semiconductor chip according to the first embodiment of the present invention.

FIG. 2 is a cross-sectional view illustrating a part of a semiconductor chip having a bump according to a second embodiment of the present invention.

FIGS. 3A to 3G are cross-sectional views illustrating the sequence of manufacturing the semiconductor chip according to the first embodiment of the present invention.

### DETAILED DESCRIPTION OF PREFERRED EMBODIMENTS OF THE INVENTION

Various embodiments of the present invention will be described in more detail in the following with reference to the accompanying drawings.

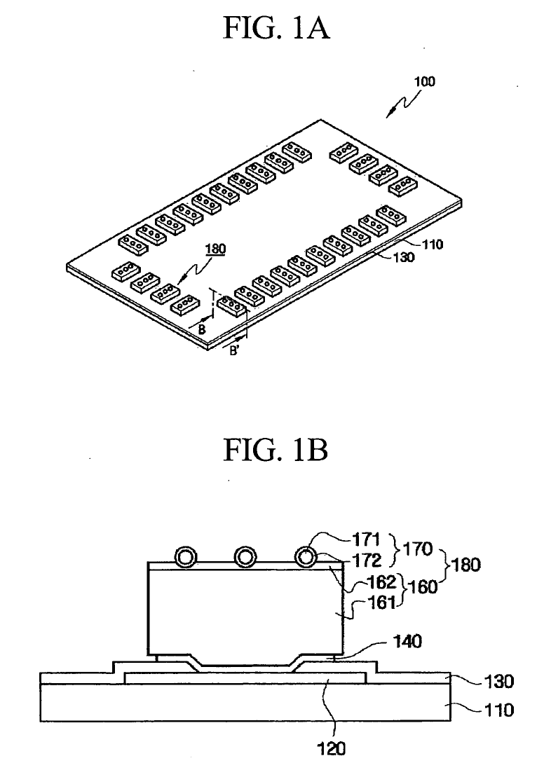

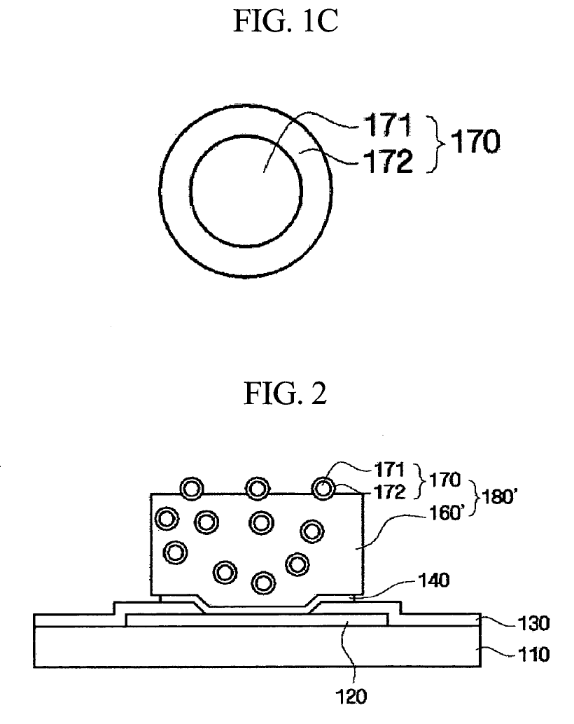

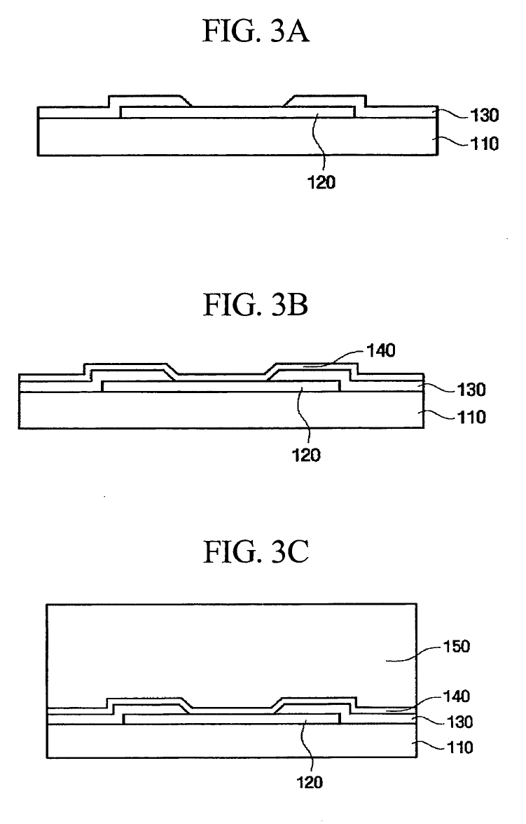

A semiconductor chip according to a first embodiment of the present invention will be described with reference to FIGS. 1A to FIG. 1C.

As shown in FIGS. 1A to 1C, the semiconductor chip 100 according to the first embodiment of the present invention includes a substrate 110, semiconductor chip pads 120, a passivation layer 130, bump support structures 140 and bumps 180.

The substrate 110 is provided with semiconductor devices thereon. That is, the substrate 110 can be made of silicon, and has a plurality semiconductor devices, such as transistors or capacitors, thereon, in combination with an insulating layer.

The chip pads 120 are formed on the substrate 110, and make an electrical connection between an external board and the semiconductor devices formed on the substrate 110. The chip pads 120 may be the uppermost interconnections on the substrate 110 and serve to make electrical connection between semiconductor devices in an external board and semiconductor devices on the substrate 110. Since the chip pads 120 may be made of aluminum or copper, their electrical resistance is low.

The passivation layer 130 may be formed on the substrate 110 to protect the semiconductor devices formed on the substrate 110. The passivation layer 130 may have openings at positions where the chip pads 120 are disposed. However, the passivation layer 130 may be partially overlapped with the chip pads 120. That is, the passivation layer 130 may partially cover the chip pads 120.

The bump support structures 140 may be provided to protect the chip pads 130, to improve adhesion between the chip pads 130 and the bumps 180, and to act as a seed layer. The bump support structures 140 may be disposed between the chip pads 130 and the bumps 180, and are made of Ti or TiW.

Since the bumps 180 may be formed to protrude from the surface of the substrate 110, they may be conveniently connected the semiconductor devices on the substrate 110 to semiconductor devices on an external board. The bumps 180 may be formed on the bump support structures 140 using an electroplating method or an electroless plating method.

Each of the bumps 180 may include a bump main body 160 and a conductive particle 170.

The bump main body 160 may be formed to protrude from the surface of the bump support structure 140. According to the present embodiment, the bump main body 160 may be formed on the bump support structure 140. However, alternatively, the bump main body 160 may be directly formed on the chip pad 120 without the bump support structure 140 interposed therebetween.

The conductive particle 170 may be disposed in an upper end portion of the bump 180, so that it may be directly in contact with an external board. The conductive particle 170 may include an elastic portion 171 and a conductive layer 172 enclosing the elastic portion 171.

Accordingly, when the conductive particle 170 is brought into contact with an external board, since the conductive particle 170 has elasticity, it is pressed and contracted, resulting in a large contact area.

An upper end portion of the bump 180 may include a plurality of conductive particles 170 therein rather than only a single conductive particle 170, so that contact area between the conductive particles and an external board may be increased. Further, since the conductive particles 170 may be disposed at almost the same depth from the upper surface of the bump 180, the conductive particles 170 may be easily brought into contact with an external board. Further, since the conductive particle 170 preferably may be of a spherical shape, it may be in contact with an object having a relatively broader area when pressure is applied thereto.

The elastic portion 171 of the conductive particle 170 may be made of polymer, and the conductive layer 172 may be a nickel (Ni) layer, a gold (Au) layer, or a double layer of nickel (Ni) and gold (Au).

Part of each of the conductive particles 170 may be embedded in the bump main body 160 in order to enhance the binding force between the conductive particles 170 and the bump main body 160, and in order to increase electrical conductivity.

The bump main body 160 may include a conductive particle-free layer 161 which contains no conductive particles therein, and a conductive particle-containing layer 162 which contains conductive particles.

The conductive particle-free layer 161 may be formed on the bump support structure 140, and may be a height that enables the conductive particle-containing layer 162 to be easily connected to an external board. The conductive particle-free layer 161 may be formed of gold (Au), copper (Cu), or nickel (Ni).

The conductive particle containing layer 162 may be formed on the conductive particle free layer 161 and may be a thickness that causes the conductive particles 170 to be exposed. That is, the conductive particle containing layer 162 may be thinner than the conductive particles 170.

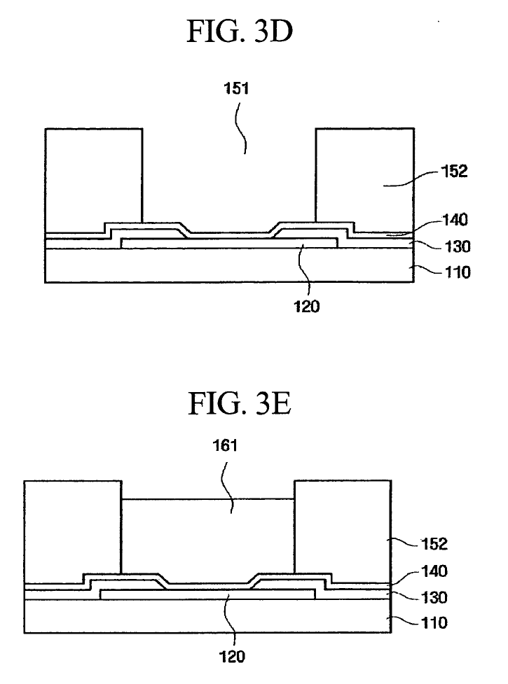

FIG. 2 illustrates a cross-section of a semiconductor chip having a bump 180′ according to a second embodiment of the present invention.

Referring to FIG. 2, conductive particles 170 may be scattered throughout the bump 180′ as shown. Accordingly, the bump 180′ may be readily formed in a single plating process.

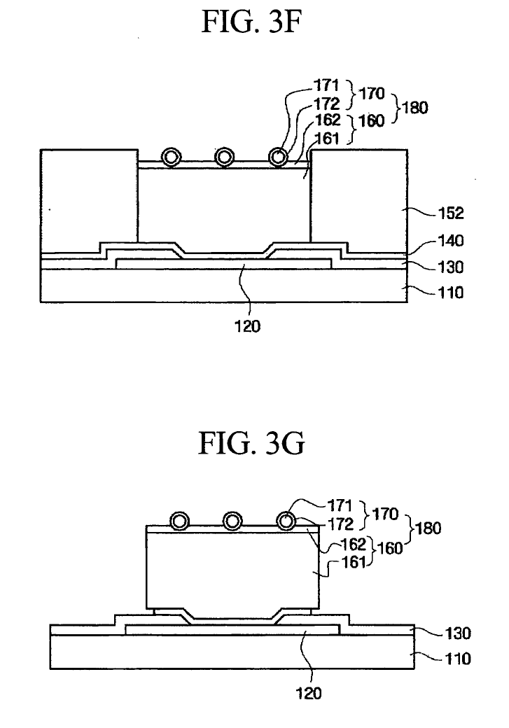

A method of manufacturing a semiconductor chip according to the first embodiment of the present invention will be described with reference to FIGS. 3A to 3G.

As shown in FIG. 3A, a substrate 110 is provided, and chip pads 120 are then formed on the substrate 110. Further, a passivation layer 130 is formed on the substrate 110.

Next, as shown in FIG. 3B, bump support structures 140 are formed on the respective chip pads 120 and on the passivation layer 130.

Next, as shown in FIG. 3C, a photoresist layer 150 is formed on the bump support structures 140.

Next, as shown in FIG. 3D, the photoresist layer 150 is partially removed from the chip pads 120, so that bump patterns 151 are formed.

Next, as shown in FIG. 3E, a first plating process may be performed to form a conductive particle-free layer 161 on the bump patterns 151. The first plating process may be performed using an electroplating method or an electroless plating method and a plating solution that does not contain conductive particles.

Next, as shown in FIG. 3F, a second plating process may be performed to form a conductive particle containing layer 162. The second plating process may be performed using a plating solution containing conductive particles 170. Here, the flow of the plating solution may be directed toward the substrate 110 so that the conductive particles 170 may be plated along with the conductive particle-containing layer 162. Since the conductive particles 170 may be disposed in an upper end portion of the bump 180 using a plating process, an outermost insulating layer may be not necessary, unlike when using conventional conductive particles in ACF. Accordingly, a step of forming an insulating layer, which may be needed in the conventional conductive particle manufacturing process, may be omitted, so that contact resistance may be improved.

Next, as shown in FIG. 3G, the photoresist layer 152 may be removed, and wet etching may be performed to leave the bump support structures 140 under the bumps 180.

The bump 180′ according to the second embodiment of the present invention may be formed by omitting a first plating processing and performing only a second plating process. Accordingly, the detailed description of a method of manufacturing the bump 180′ will not be repeated.

Hereinafter, the method of mounting the semiconductor chips according to the embodiments of the present invention on an external board will be described.

In order to mount the semiconductor chips according to the embodiments of the present invention on an external board, a Non Conductive Film (NCF) or a Non Conductive Paste (NCP) may be first disposed on the external board. Next, the semiconductor chips may be aligned on the NCF or NCP such that the semiconductor chips and the external board may be electrically connected, and conductive particles may be brought into contact with pads of the external board. At this time, the conductive particles contract due to their elasticity and to pressure and heat applied thereto, so that contact areas between the conductive particles and the pads of the external board may be increased. Further, the semiconductor chip may be adhered to the external board by the NCF or the NCP.

Alternatively, the semiconductor chip may be mounted on the external board by under-filling an adhesive material instead of using the NCF or the NCP.

The semiconductor chips according to the embodiment of the present invention may be packaged in a variety of manners, such as Chip-On-Glass (COG), Chip-On-Film (COF) or Tape Carrier Package (TCP). Further, the bumps used in the semiconductor chips according to the embodiments of the present invention may be formed on an external board on which a semiconductor chip may to be mounted, so that the bumps may be used for semiconductor chip mounting.

The above described semiconductor chip and the method of manufacturing the same have the following advantages.

First, the conductive particles may be disposed only on an upper end portion of the bump of the semiconductor chip. That is, other portions of the bump, which do not participate in electrical conduction, do not contain conductive particles. Accordingly, anisotropic conduction may be effectively induced.

Second, since the bump in this invention may contain fewer conductive particles than conventional bumps, the semiconductor chip and the method of manufacturing the same according to the present invention are cost-effective.

Third, since the conductive particles may be fixed in the bump during a plating process, an insulating layer is not necessary in order to fix the conductive particles to an object. Accordingly, it is possible to reduce the manufacturing cost.

Fourth, since the conductive particle may be fixed to the bump in a manner such that part of the conductive layer of the conductive particle is exposed to the air, the contact resistance between the conductive particle and an external board can be reduced.

While the present invention has been shown and described with reference to exemplary embodiments thereof, it will be understood by those having ordinary skill in the art that various changes may be made in the form and details without departing from the spirit and scope of the present invention as defined by the following claims. Therefore, it should be understood that the above-described embodiments have been provided only in a descriptive sense and are not to be construed as placing any limitation on the scope of the invention.

What is claimed is:

1. A semiconductor chip comprising:
a plurality of chip pads; and
a plurality of bumps formed on respective chip pads, each bump comprising a bump main body electrically connected to the chip pad and a conductive particle disposed on the bump main body and exposed, each conductive particle including an elastic portion made of an elastic material and a conductive layer enclosing the elastic portion.

2. The semiconductor chip of claim 1, wherein part of the conductive particle disposed at an upper end portion of the bump main body is disposed in the bump main body.

3. The semiconductor chip of claim 1, wherein the bump main body is a stacked structure in which a conductive particle-containing layer is stacked on a conductive particle-free layer.

4. The semiconductor chip of claim 1, wherein the bump main body has one or more conductive particles embedded therein.

5. The semiconductor chip of claim 1, wherein the bump main body comprises gold (Au), nickel (Ni), copper (Co), or a combination thereof.

6. The semiconductor chip of claim 1, wherein the conductive particle has a substantially spherical shape.

7. The semiconductor chip of claim 1, wherein the conductive layer of the conductive particle is exposed.

8. A method of manufacturing a semiconductor chip, comprising:
providing a semiconductor chip having a plurality of chip pads; and
forming bumps on respective chip pads, each bump comprising a bump main body electrically connected to the chip pad and a conductive particle disposed on the bump main body and exposed, the conductive particle including an elastic portion made of an elastic material and a conductive layer enclosing the elastic material.

9. The manufacturing method of claim 8, wherein forming the bumps comprises:
forming a lower bump through a plating process using a plating solution not containing conductive particles; and
forming an upper bump through a plating process using a plating solution containing conductive particles.

10. The manufacturing method of claim 8, wherein forming the bump comprises forming the bump main body having conductive particles embedded therein through a plating process using a plating solution containing conductive particles.

11. The manufacturing method of claim 8, wherein the bump main body comprises gold (Au), nickel (Ni), copper (Cu), or a combination thereof.

12. The manufacturing method of claim 8, wherein the conductive particle has a substantially spherical shape.

13. The manufacturing method of claim 8, wherein the conductive particle does not include an insulating layer as an outermost layer.
